(19) United States
(12) Patent Application Publication
(10) Pub. No.: US 2025/0316660 A1
(43) Pub. Date: Oct. 9, 2025

(54) Manufacturing Method for Photodiode Integrating Hall Induction, Photodiode, and Photoelectric Keyboard

(71) Applicants: Wei SHEN, Shenzhen (CN); Ke CHEN, Shenzhen (CN)

(72) Inventors: Wei SHEN, Shenzhen (CN); Ke CHEN, Shenzhen (CN)

(21) Appl. No.: 18/777,579

(22) Filed: Jul. 19, 2024

(30) Foreign Application Priority Data
Apr. 8, 2024 (CN) 202410410023.3

(51) Int. Cl. H01L 25/16; H01L 21/56; H01L 23/00

(52) U.S. Cl. CPC H01L 25/167; H01L 21/561; H01L 24/83; H01L 2224/838

(57) ABSTRACT

In a manufacturing method for the photodiode integrating Hall induction, a support is provided, there is a base and a plurality of pins on the support, and the base has a first packaging cavity and a second packaging cavity, and there is a plurality of pins on the base; the visible light emitting chip and the color control chip are fixed in the first packaging cavity, and the Hall induction chip is fixed in the second packaging cavity; the electrodes of the visible light emitting chip, the color control chip and the Hall induction chip are welded to the pins respectively to form the electrical control loop; the first packaging cavity is dispensed and packaged with epoxy resin adhesive or silica gel, and baked and cured; and the second packaging cavity is dispensed and packaged with filtering adhesive, and baked and cured to form the photodiode integrating Hall induction.

### CROSS REFERENCE TO THE RELATED APPLICATIONS

This application is based upon and claims priority to Chinese Patent Application No. 202410410023.3, filed on Apr. 8, 2024, the entire contents of which are incorporated herein by reference.

### TECHNICAL FIELD

The present invention relates to the photodiodes, in particular to a manufacturing method for the photodiode integrating Hall induction, a photodiode, and a photoelectric keyboard.

### BACKGROUND

With the continuous development of science and technology, photodiode as a new-generation light source is applied in a more and more extensive range, and has been deeply involved in the people's work and life. In particular, in the field of photoelectric mechanical keyboard, photodiode plays a decisive role.

As a kind of keyboard product based on advanced photoelectric technologies, the photoelectric mechanical keyboard has particularly strict requirements for photodiode. The photoelectric mechanical keyboard requires that the photodiode shall not only have the functions of decoration and lighting, but also be able to transmit the light signal accurately, and achieve precise operation feedback. Undoubtedly, this poses a higher challenge to the performance and technical indicators of the photodiode.

However, most of the traditional light-emitting diodes and infrared diodes adopt separate packaging process, and each diode has only single photoelectric characteristic. This means that in the application of the photoelectric mechanical keyboard, in order to achieve the dual function of lighting decoration and signal transmission, we must use two different photoelectric components and switching components. This approach not only increases the complexity of circuit design, especially for the circuit boards in smaller size, the difficulty in design is exponentially increased.

In addition, the use of various optoelectronic components is bound to lead to an increase in product application costs. More manpower, physical and financial resources shall be invested in purchasing of raw materials, and assembly and testing during the process of production, so as to undoubtedly increase the production cost of enterprises and reduce the market competitiveness of products.

### SUMMARY

The present invention is intended to solve, at least to a certain extent, one of the technical problems in the related technology. To this end, the present invention aims to provide a manufacturing method for the photodiodes integrating Hall induction, a color photodiode, and a photoelectric keyboard.

To achieve the aforesaid purposes, on the one hand, the manufacturing method for the photodiodes integrating Hall induction according to the embodiments of the present invention includes:
A support is provided; there is a base and a plurality of pins on the said support; and the said base has a first packaging cavity and a second packaging cavity, and there is a plurality of the said pins on the said base;
The visible light emitting chip and the color control chip are fixed in the said first packaging cavity, and the Hall induction chip is fixed in the said second packaging cavity; the said visible light emitting chip includes the red light emitting chip, the blue light emitting chip, and the green light emitting chip;
The electrodes of the said visible light emitting chip, the color control chip and the Hall induction chip are welded to the said pins respectively to form the electrical control loop;
The said first packaging cavity is dispensed and packaged with epoxy resin adhesive or silica gel, and baked and cured; and the said second packaging cavity is dispensed and packaged with filtering adhesive, and baked and cured to form the photodiode integrating Hall induction. In the said photodiode integrating Hall induction, there are Hall induction electrical control loop and color electrical control loop, which are independent with each other.

In addition, the manufacturing method for the photodiodes integrating Hall induction according to the aforesaid embodiments of the present invention may also have the following additional technical characteristics:

According to one embodiment of the present invention, the visible light emitting chip and the color control chip are fixed in the said first packaging cavity, and the Hall induction chip is fixed in the said second packaging cavity, including:
The chip fixing adhesive is dispensed in the first designated area in the said first packaging cavity and the second designated area of the said second packaging cavity respectively;
The color control chip, the red light emitting chip, the blue light emitting chip, and the green light emitting chip are placed in the said first designated area, and the predetermined distance is maintained, and the said red light emitting chip, blue light emitting chip and green light emitting chip are bonded with the said chip fixing adhesive;
The Hall induction chip is placed in the said second designated area, and the said Hall induction chip is bonded with the chip fixing adhesive;
The said support is delivered into a curing device and baked at the temperature of 150-180° C. and for 60-80 minutes for curing.

According to one embodiment of the present invention, a plurality of the said pins include a negative power pin, a Hall input pin, a color input pin, a Hall output pin, a color output pin, and a positive power pin;
The electrodes of the said visible light emitting chip, the color control chip, and the Hall induction chip are welded to the said pins respectively to form an electrical control loop, including:

According to the electrical wiring diagram of the said photodiode, the said color input pin, the color output pin, the positive power pin, and the negative power pin are welded with the color control chip and the visible light emitting chip to form the color electrical control loop, and the Hall input pin, the Hall output pin, the positive power pin, and the negative power pin are welded with the said Hall induction chip to form the Hall induction electrical control loop.

According to one embodiment of the present invention, the said first packaging cavity is dispensed and packaged with epoxy resin adhesive or silica gel, and backed and cured; and the said second packaging cavity is dispensed and packaged with the filtering adhesive, and baked and cured, to form the photodiode integrating Hall induction, including:
The first packaging cavity is dispensed and packaged with epoxy resin adhesive or silica gel, and the second packaging cavity is dispensed and packaged with filtering adhesive;
The support dispensed and packaged is transferred into the baking equipment, so as to bake and cure the support at a predetermined temperature, to form the photodiode integrating Hall induction.

According to one embodiment of the present invention, the said support dispensed with packaging adhesive is transferred into the baking equipment, so as to bake and cure the support at a predetermined temperature, including:
The support dispensed and packaged is baked in the first stage; in the said first stage, the baking temperature is 60-100° C., and the baking time is 60-80 minutes;
The support dispensed and packaged is baked in the second stage; in the said second stage, the baking temperature is 140-160° C., and the baking time is 60-80 minutes.

According to one embodiment of the present invention, the said support is an integrated support including a plurality of bases; the said first packaging cavity is dispensed and packaged with epoxy resin adhesive or silica gel, and baked and cured; and the said second packaging cavity is dispensed and packaged with filtering adhesive, and baked and cured to form the photodiode integrating Hall induction, also including:

The said integrated support is cut to form a plurality of single photodiodes, and each said single photodiode includes a base and the pins on the base.

In the second aspect, the present invention also provides a kind of photodiode integrating Hall induction, which is manufactured by the method as described above.

In the third aspect, the present invention also provides a kind of photoelectric keyboard, which includes a light-emitting diode (LED) key module, and in each said LED key module, there are the said photodiodes integrating Hall induction as described above.

The manufacturing method for the photodiodes integrating Hall induction, the photodiode, and the photoelectric keyboard are provided according to the present invention. Among others, by this method, the red light emitting chip, the blue light emitting chip, the green light emitting chip, the color control chip and the Hall induction chip are integrated and packaged to form the photodiode integrating Hall induction, which can integrate the functions of decoration, lighting and signal transmission., and achieve the photoelectric mechanical keyboard in a single component. The Hall induction circuit is characterized by quick response, high sensitivity, and strong anti-interference performance, and can be used as the electromagnetic induction switch. The color control loop can output red, green, blue and seven-color light through the control chip, which can be used for decoration and graphic display. In addition, in the applications, this photodiode integrating Hall induction can reduce the electric components, save the circuit board space, simplify the wiring, and reduce the cost.

Some additional aspects and advantages of the present invention will be given in the Description below, and some additional aspects and advantages will become apparent from the Description below, or will be learned through the practice of the present invention.

### BRIEF DESCRIPTION OF THE DRAWINGS

In order to make a clearer explanation to the technical scheme in the embodiments of the present invention or in the prior art, the appended drawings to be used in the embodiments or description of the prior art are briefly introduced below. It is obvious that the appended drawings described below are only certain embodiments recorded in the present invention, and the ordinary persons skilled in the art can also obtain other appended drawings on the basis of the structures shown in such appended drawings without the contribution of creative labor.

FIG. 1 is the flow chart for manufacturing method for the photodiodes integrating Hall induction in the embodiments of the present invention;

FIG. 2 is the schematic diagram for the structure of the photodiodes integrating Hall induction in the embodiments of the present invention;

FIG. 3 is the wiring diagram for the photodiodes integrating Hall induction in the embodiments of the present invention;

FIG. 4 is the equivalent circuit diagram for the photodiodes integrating Hall induction in the embodiments of the present invention;

The realization of the purpose, the functional characteristics and advantages of the present invention will be further explained in conjunction with the embodiments and with reference to the appended drawings.

### DETAILED DESCRIPTION OF THE EMBODIMENTS

The embodiments of the present invention are described in detail below, the examples of the said embodiments are shown in the appended drawings, where identical or similar labels are used to indicate the identical or similar components or the components with identical or similar functions from beginning to end. The embodiments described below with reference to the appended drawings are exemplary and intended to interpret the present invention, and shall not be construed as the limitations on the present invention. Based on the embodiments of the present invention, all other embodiments obtained by ordinary skilled persons in the art without contribution of creative labor shall fall within the protection scope of the present invention.

In the description of the present invention, it shall be understood that the oriental and

positional relationship indicated by the terms such as “center”, “longitudinal”, “transverse”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, “axial”, “circumferential”, and “radial” are based on the oriental and positional relationship indicated in the appended drawings, and for description of the present invention and simplification of the description only, but not intended to indicate or imply that the device or component referred to must have a particular orientation, and must be constructed and operated in a particular orientation. Therefore, such oriental and positional relationship shall not be interpreted as the limitation on the present invention.

In addition, the terms “first” and “second” shall be used for descriptive purpose only, and shall not be understood to indicate or imply relative importance or to indicate implicitly the quantity of the technical features as indicated. Thus, a feature defined as “first” or “second” may include, explicitly or implicitly, one or more such features. In the description of the present invention, “multiple” means two or more unless otherwise expressly defined.

In the present invention, unless otherwise expressly specified and defined, the terms “installation”, “association”, “connection”, and “fixing”, shall be understood in a broad sense; for example, it includes fixed connection, or detachable connection, or integrated connection; mechanical connection, or electrical connection; direct connection, or indirect connection through an intermediate medium, or connection within two components. For ordinary skilled persons in the art, the specific meaning of the above terms in the present invention can be understood according to the specific circumstances.

In the present invention, unless otherwise expressly specified and defined, the first feature may include direct contact between the first and second features “above” or “under” the second features, or may include contact between the first and second features not directly but through another feature between them. Furthermore, the first feature “above”, “over” and “on” the second feature include the first feature being directly above and diagonally above the second feature, or simply indicating that the first feature is higher in level than the second feature. The first feature “under”, “below” and “underneath” the second feature include the first feature being directly below and diagonally below the second feature, or simply indicating that the first feature is lower in level than the second feature.

The manufacturing method for the photodiodes integrating Hall induction, the photodiode, and the photoelectric keyboard in the embodiments of the present invention are described in detail below with reference to the appended drawings.

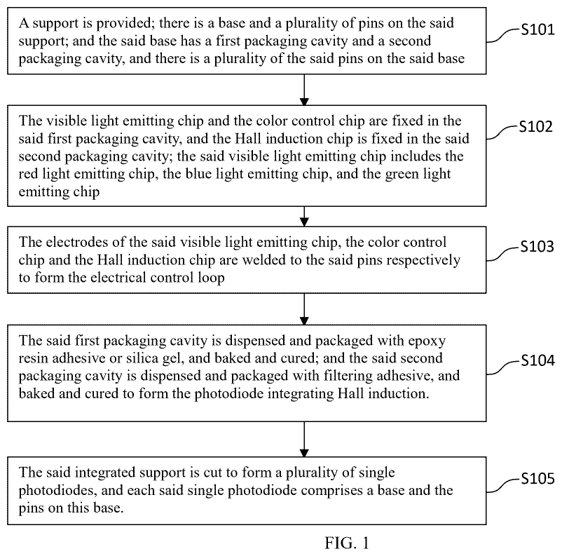

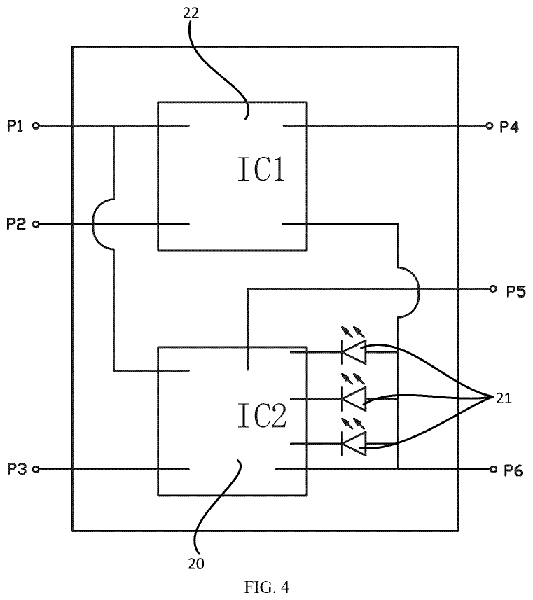

With reference to FIG. 1 to FIG. 4, the manufacturing method for the photodiodes integrating Hall induction provided according to the embodiments of the present invention includes:
S101. A support 10 is provided; there is a base 101 and a plurality of pins 102 on the said support 10; and the said base 101 has a first packaging cavity P10 and a second packaging cavity P11, and there is a plurality of the said pins 102 on the said base 101;
The base 101 is generally made of plastic material. The pins 102 are fixed on the base 101 and generally made of metal material, and used to connect the visible light emitting chip 21, the color control chip 20, and the Hall induction chip 22. Exemplarily, the base 101 is molded by injection molding process to achieve the shape and size as required; after the plastic is cured and molded in the injection molding process, the pins 102 are fixed and integrated with the base 101.

The first packaging cavity P10 is used for installation of the visible light emitting chip 21 and the color control chip 20, while the second packaging cavity P11 is used for installation of the Hall induction chip 22.
S102. The visible light emitting chip 21 and the color control chip 20 are fixed in the said first packaging cavity P10, and the Hall induction chip 22 is fixed in the said second packaging cavity P11; the said visible light emitting chip 21 includes a red light emitting chip, a blue light emitting chip, and a green light emitting chip.

At this step, the visible light emitting chip 21 (i.e. the red light emitting chip, the green light emitting chip, and the blue light emitting chip) and the color control chip 20 are fixed in the first packaging cavity P10. It is possible to fix them on the base 101 by means of bonding, and ensure that they are located at the specified position respectively. The Hall induction chip 22 is fixed in the second packaging cavity P11. Similarly, it is possible to fix the Hall induction chip 22 by means of bonding, and ensure its stability.

The color control chip 20 and the visible light chip 21 are located in the same packaging cavity (i.e. the first packaging cavity P10), so as to facilitate the electrical connection between the color control chip 20 and the visible light chip 21. The red light emitting chip, the green light emitting chip and the blue light emitting chip can mix and emit the light in different colors, so as to provide the users with a rich visual experience. The color control chip 20 is used to control the changes in luminance and color of these visible light emitting chips 21 to achieve different light effects. The Hall induction chip 22 is arranged in the second packaging cavity P11 independently, so as to realize the isolation of the Hall induction chip 22 from the color control chip 20 and the visible light emitting chip 21, and ensure the independent and stable operation of the Hall induction chip 22. The Hall induction chip 22 can detect the changes in the magnetic field and convert the changes in the magnetic field changes into electrical signals, so as to achieve fast and precise switching control.
S103. The electrodes of the said visible light emitting chip 21, the color control chip 20, and the Hall induction chip 22 are welded with the said pins 102 respectively to form the electrical control loop. That is, the electrodes of the visible light emitting chip 21, the color control chip 20, and the Hall induction chip 22 shall be connected with the pins 102 by welding and other methods to form the electrical control loop. It is required to ensure the good contact and stability of welding to guarantee the normal operation and stability of the circuit. Once the welding is completed, the electrical control loop formed will allow the external circuit to communicate with the photodiode via the pins 102.
S104. The said first packaging cavity P10 is dispensed and packaged with epoxy resin adhesive or silica gel, and baked and cured; and the said second packaging cavity P11 is dispensed and packaged with filtering adhesive, and baked and cured to form the photodiode integrating Hall induction. In the said photodiode integrating Hall induction, there are Hall induction electrical control loop and color electrical control loop, which are independent with each other.

At this step, epoxy resin adhesive or silica gel is used to package the first packaging cavity P10; after the packaging, it is possible to protect the visible light emitting chip 21 and the color control chip 20 from physical damage and environmental impact, such as dust, moisture and mechanical impact. At the same time, after the curing, these epoxy resin adhesive or silica gel can form a hard protective layer, and also have good light transmission, so as to guarantee the optical effect of the photodiode. The packaging of the second packaging cavity P11 with the filtering adhesive is helpful to protect the Hall induction chip 22, and ensure that the Hall induction chip 22 only responds to the light with specific wavelength, improve the sensitivity and accuracy of the Hall induction chip 22, and ensure the optical characteristics and stable environment required for its normal operation.

The manufacturing method for the photodiodes integrating Hall induction is provided according to the present invention. Among others, by this method, the red light emitting chip, the blue light emitting chip, the green light emitting chip, the color control chip 20 and the Hall induction chip 22 are integrated and packaged to form the photodiode integrating Hall induction, which can integrate the functions of decoration, lighting and signal transmission., and achieve the photoelectric mechanical keyboard in a single component. The Hall induction circuit is characterized by quick response, high sensitivity, and strong anti-interference performance, and can be used as the electromagnetic induction switch. The red, green, blue and seven-color light is output through the color control chip 20, and can be used for decoration and graphic display. In addition, in the applications, this photodiode integrating Hall induction can reduce the electric components, save the circuit board space, simplify the wiring, and reduce the cost.

In one embodiment of the present invention, the step S102 includes:

The chip fixing adhesive is dispensed in the first designated area in the said first packaging cavity P10 and the second designated area in the said second packaging cavity P11 respectively. The fixing adhesive in the first designated area is used to bond and fix the visible light emitting chip 21 and the color control chip 20, and the fixing adhesive in the second designated area is used to bond and fix the Hall induction chip 22. After curing at a high temperature, the fixing adhesive can provide sufficient mechanical strength to maintain the stability of the visible light emitting chip 21, the color control chip 20, and the Hall induction chip 22.

The color control chip 20, the red light emitting chip, the blue light emitting chip, and the green light emitting chip are placed in the said first designated area and the predetermined distance is maintained, and the said red light emitting chip, the blue light emitting chip and the green light emitting chip are bonded with the said chip fixing adhesive. That is, the bottoms of the color control chip 20, the red light chip, the blue light chip and the green light chip are placed at the positions in the first designated area where the adhesive shall be dispensed, and the color control chip 20, the red light chip, the blue light chip and the green light chip are fixed at different positions in the first packaging cavity P10 with the fixing adhesive.

The Hall induction chip 22 is placed in the said second designated area, and the said Hall induction chip 22 is bonded with the chip fixing adhesive. That is, the bottom of the Hall induction chip 22 is placed on the fixing adhesive in the second designated area, and the Hall induction chip 22 is fixed in the second packaging cavity P11 with the fixing adhesive.

The said support 10 is delivered into the curing equipment, and baked at the temperature of 150-180° C. and for 60-80 minutes for curing. At this step, by baking at the temperature ranging from 150 to 180° C. and for 60 to 80 minutes, the chip fixing adhesive can be cured completely to form a solid structure, so as to maintain the stability of the color control chip 20, the visible light emitting chip 21, and the Hall induction chip 22 in the service for a long term. The combination of temperature and time is selected on an experimental basis to improve the performance of the chip fixing adhesive to the maximum extent, while protecting the color control chip 20, the visible light emitting chip 21, and the Hall induction chip 22 from thermal damage.

Through the above steps, it is possible to ensure that the color control chip 20, the visible light emitting chip 21, and the Hall induction chip 22 shall be fixed in the support reliably, so as to ensure the quality of such photodiodes integrating Hall induction during the process of manufacturing and the performance of such photodiodes integrating hall induction in the final application. Moreover, it is helpful to improve the reliability and durability of the product, and the simple process results in the optimized production efficiency and cost control.

In one embodiment of the present invention, a plurality of the said pins 102 include a negative power pin P1, a Hall input pin P2, a color input pin P3, a Hall output pin P4, a color output pin P5, and a positive power pin P6. As part of the power loop, the negative power pin P1 provides the common ground wire connection to the chip. The positive power pin P6 provides the positive power voltage to supply the energy required by the color control chip 20 and the Hall induction chip 22. The color input pin P3 receives the signal from the external controller, which is used to control the operating state and the light efficiency mode of the color control chip 20, so as to control the operation of the red light emitting chip, the blue light emitting chip and the green light emitting chip. The color output pin P5 output the signal processed by the color control chip 20 to drive the visible light emitting chip 21 to produce the light effect as required. The Hall input pin P2 receives the signal produced by the change in the external magnetic field, and transmits the signal to the Hall induction chip 22 for processing. The Hall output pin P4 outputs the signal processed by the Hall induction chip 22 to control the external circuit or equipment.

The said step S103 includes: According to the electrical wiring diagram for the said photodiode, the said color input pin P3, the color output pin P5, the positive power pin P6, and the negative power pin P1 are welded with the color control chip 20 and the visible light emitting chip 21 to form the color electrical control loop, and the Hall input pin P2, the Hall output pin P4, the positive power pin P6, and the negative power pin P1 are welded with the said Hall induction chip 22 to form the Hall induction electrical control loop.

The color electrical control circuit can control the changes in luminance and color of the visible light emitting chip 21 to achieve rich light effects. The Hall induction electrical control loop is used to convert the changes in the external magnetic field into the electrical signal, and output the electrical signal to the external circuit to achieve fast and precise switching control.

Through this welding and wiring step, the light-emitting diode can form the independent Hall induction electrical control circuit and color control circuit, so as to ensure the stability and long-term reliability of the photodiode in electrical performance, and lay the foundation for high efficiency and accurate control of the photoelectric mechanical keyboard and other application products.

In one embodiment of the present invention, the said step 104 includes:

The first packaging cavity P10 is dispensed and packaged with epoxy resin adhesive or silica gel, and the second packaging cavity P11 is dispensed and packaged with filtering adhesive. That is, after the color control chip 20, the visible light emitting chip 21, and the Hall induction chip 22 are fixed in the first packaging cavity, and the Hall induction chip 22 is fixed in the second packaging cavity P11, epoxy resin adhesive or silica gel is dispensed in the first packaging cavity P10, so that the first packaging cavity P10 is filled with epoxy resin adhesive or silica gel, and the color control chip 20 and the visible light emitting chip 21 can be enclosed completely in epoxy resin adhesive or silica gel; filtering adhesive is dispensed in the second packaging cavity P11, so that the second packaging cavity P11 is filled with filtering adhesive, and the Hall induction chip 22 can be enclosed completely in the filtering adhesive.

After curing, epoxy resin adhesive or silica gel can provide a strong protective layer for the color control chip 20 and the visible light emitting chip 21. Epoxy resin adhesive or silica gel has the features of resistance to chemical corrosion, resistance to high temperature, and resistance to mechanical shock, and can adapt to different service environments. At the same time, epoxy resin adhesive or silica gel has good light transmission, so that it will not hinder the transmission of light, and guarantee the optical effect of the photodiode.

The support 10 dispensed and packaged is transferred into the baking equipment, so as to bake and cure the support 10 at a predetermined temperature, to form the photodiode integrating Hall induction. The filtering adhesive is dispensed and packaged in the second packaging cavity P11 to protect the Hall induction chip 22 and ensure that it only responds to the light with specific wavelength. That is, the filtering adhesive can not only protect the chip, but also filter out the unnecessary light waves, and improve the sensitivity and accuracy of Hall induction chip 22. That is, after the dispensing and packaging is completed, the support 10 is transferred into the baking equipment. The support 10 will be baked at a predetermined temperature for a period of time in order to completely cure epoxy resin adhesive or silica gel and the filtering adhesive.

Through the aforesaid packaging and curing steps, it is possible to ensure that the color control chip 20 and the visible light emitting chip 21 can be packaged in epoxy resin adhesive or silica gel steadily, and the Hall induction chip 22 can be packaged in filtering adhesive steadily, to achieve the isolation from the external environment, and improve the quality and durability of the photodiode integrating Hall induction.

In one embodiment of the present invention, the said support 10 dispensed and packaged is transferred into the baking equipment, so as to bake and cure the support 10 at a predetermined temperature, including:
The support 10 dispensed and packaged is baked in the first stage; in the said first stage, the baking temperature is 60-100° C., and the baking time is 60-80 minutes;
The support 10 dispensed and packaged is baked in the second stage; in the said second stage, the baking temperature is 140-160° C., and the baking time is 60-80 minutes. Baking and curing is a process to be controlled in a precise way. The selection of

temperature and time has an immediate impact on performance of the packaging material and the final protection effect. Too high temperature or too long time may result in the performance degradation of the packaging material, while too low temperature or too short time may result in the incomplete curing of the packaging material.

In this embodiment, the curing process of dispensing and packaging is divided into two baking stages, i.e. the baking at the first stage and the baking at the second stage. At the first stage of baking, the baking temperature is 60-100° C., and the baking time is 60-80 minutes. This temperature range is selected for gradual curing and drying of epoxy resin adhesive or silica gel and filtering adhesive. In this baking process, the solvent or volatile components in epoxy resin adhesive or silica gel and filtering adhesive are gradually evaporated, making the colloidal material stronger and bonded tightly to the photodiode chip. At the second stage of baking, the baking temperature is 140-160° C., and the baking time is 60-80 minutes. The high temperature is helpful to cure and reinforce epoxy resin adhesive or silica gel and filtering adhesive to ensure its adhesion with the photodiode chip and its stability. This baking process is also helpful to improve the heat resistance and weather resistance to adapt to various working environments and conditions.

By baking and curing at such two stages, epoxy resin adhesive/silica gel and filtering adhesive of the photodiodes packaged can achieve the curing and stabilizing effect as required, so as to ensure that the photodiodes shall have good performance, reliability and durability in use.

In some embodiments of the present invention, the said support 10 is an overall support 10 including a plurality of bases 101; after the said step S104, it also includes:
S105. The said overall support 10 is cut to form a plurality of single photodiodes, and each said single photodiode includes a base 101 and the pins on the base 101.

In the specific manufacturing process, the support 10 and the pins are formed by injection molding process; furthermore, due to the small size of the photodiode, in order to achieve the mass production, an overall support 10 is usually formed during the process of injection molding; on the overall support 10, there is a plurality of bases 101, and the whole pin passes through the bases 101. Therefore, after the packaging is completed, the single photodiode after the corresponding base 101 is molded may be cut with the cutting process to form a plurality of single photodiodes, so as to achieve mass production, improve the production efficiency, and guarantee the consistency of product quality.

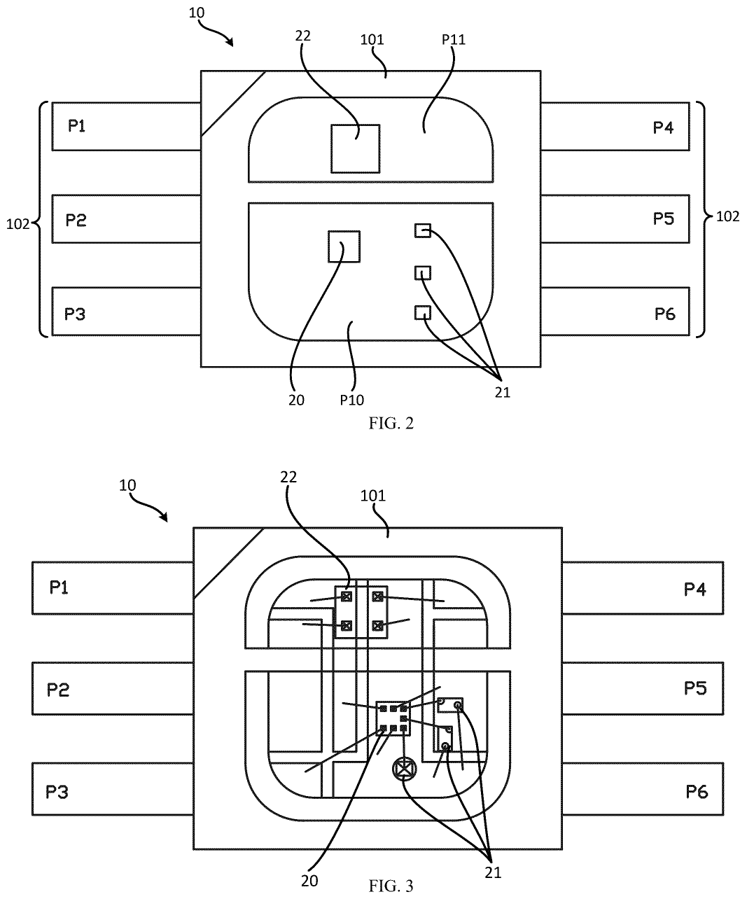

With reference to FIG. 2 to FIG., the present invention also provides a kind of photodiode integrating Hall induction, which is manufactured by the method as descried above. The photodiode can integrate the functions of decoration, lighting and signal transmission, and achieve the application production in a single component.

The present invention also provides a kind of photoelectric keyboard including an LED key module, and each said LED key module has the photodiode integrating Hall induction as described above.

The photoelectric keyboard provided in the embodiments of the present invention adopts the photodiode integrating the Hall induction chip 22 to realize the functions of decoration, lighting and signal transmission simultaneously. The Hall induction switch can replace the traditional contact switch and photoelectric switch, and have the characteristics of quick response, high sensitivity, and strong anti-interference performance; due to its unique integrated packaging, it is possible to reduce electronic components, save circuit board space, and simplify wiring in the application.

In the description of this Secification, the description with the terms such as “an embodiment”, “some embodiments”, “examples”, “specific examples”, or “some examples” means that the specific features, structures, materials, or characteristics described on the basis of such emobidments or examples are included in at least one embodiment or example of the present invention. In this Specification, the schematic representations of the above terms must not be directed to the same embodiments or examples. Furthermore, the specific features, structures, materials or characteristics so described may be combined in a suitable manner in any one or more embodiments or examples. In addition, without the conflict with each other, the persons skilled in the art may incorporate and combine the different embodiments or examples described in this Specification and the characteristics of different embodiments or examples.

Only the preferred embodiments of the present invention are described above without limitation on the claims of the present invention. All equivalent structure transformations made under the inventive concept of the present invention and with the contents of the Specification and the appended drawings of the present invention, or the direct/indirect application thereof in other related technical fields are included within the scope of patent protection of the present invention.

What is claimed is:

1. A manufacturing method for photodiodes integrating Hall induction, comprising:
arranging a support, wherein there is a base and a plurality of pins on the support; and the base has a first packaging cavity and a second packaging cavity, and the plurality of pins are arranged on the base;
fixing a visible light emitting chip and a color control chip in the first packaging cavity, and fixing a Hall induction chip in the second packaging cavity, wherein the visible light emitting chip comprises a red light emitting chip, a blue light emitting chip, and a green light emitting chip;
welding electrodes of the visible light emitting chip, the color control chip and the Hall induction chip to the plurality of pins respectively to form an electrical control loop;
dispensing and packaging the first packaging cavity with an epoxy resin adhesive or a silica gel, and performing baking and curing; and dispensing and packaging the second packaging cavity with a filtering adhesive, and performing baking and curing to form a photodiode integrating Hall induction, wherein in the photodiode integrating Hall induction, there are a Hall induction electrical control loop and a color electrical control loop, wherein the Hall induction electrical control loop and the color electrical control loop are independent with each other.

2. The manufacturing method for the photodiodes integrating Hall induction according to claim 1, wherein the step of fixing the visible light emitting chip and the color control chip in the first packaging cavity and fixing the Hall induction chip in the second packaging cavity comprises:
dispensing a chip fixing adhesive in a first designated area in the first packaging cavity and a second designated area in the second packaging cavity respectively;
placing the color control chip, the red light emitting chip, the blue light emitting chip and the green light emitting chip in the first designated area, maintaining a predetermined distance, and bonding the red light emitting chip, the blue light emitting chip and the green light emitting chip with the chip fixing adhesive;
placing the Hall induction chip in the second designated area, and bonding the Hall induction chip with the chip fixing adhesive; and
delivering the support into a curing device and baking the support at a temperature of 150° C.-180°C. and for 60 minutes-80 minutes for curing.

3. The manufacturing method for the photodiodes integrating Hall induction according to claim 1, wherein the plurality of pins comprise a negative power pin, a Hall input pin, a color input pin, a Hall output pin, a color output pin, and a positive power pin;
the step of welding the electrodes of the visible light emitting chip, the color control chip and the Hall induction chip to the plurality of pins respectively to form the electrical control loop comprises:
according to an electrical wiring diagram of the photodiode, welding the color input pin, the color output pin, the positive power pin and the negative power pin with the color control chip and the visible light emitting chip to form the color electrical control loop, and welding the Hall input pin, the Hall output pin, the positive power pin and the negative power pin with the Hall induction chip to form the Hall induction electrical control loop.

4. The manufacturing method for the photodiodes integrating Hall induction according to claim 1, wherein the first packaging cavity is dispensed and packaged with the epoxy resin adhesive or the silica gel, and backed and cured; and the second packaging cavity is dispensed and packaged with the filtering adhesive, and baked and cured, to form the photodiode integrating Hall induction, comprising:
the first packaging cavity is dispensed and packaged with the epoxy resin adhesive or the silica gel, and the second packaging cavity is dispensed and packaged with the filtering adhesive; and
the support dispensed and packaged is transferred into a baking equipment to bake and cure the support at a predetermined temperature, to form the photodiode integrating Hall induction.

5. The manufacturing method for the photodiodes integrating Hall induction according to claim 4, wherein the support dispensed with the packaging adhesive is transferred into the baking equipment to bake and cure the support at the predetermined temperature, comprising:
the support dispensed and packaged is baked in a first stage; in the first stage, a baking temperature is 60° C.-100° C., and a baking time is 60 minutes-80 minutes; and
the support dispensed and packaged is baked in a second stage; in the second stage, a baking temperature is 140° C.-160° C., and a baking time is 60 minutes-80 minutes.

6. The manufacturing method for the photodiodes integrating Hall induction according to claim 1, wherein the support is an integrated support comprising a plurality of bases; the first packaging cavity is dispensed and packaged with the epoxy resin adhesive or the silica gel, and baked and cured; and the second packaging cavity is dispensed and packaged with the filtering adhesive, and baked and cured to form the photodiode integrating Hall induction, also comprising:
the integrated support is cut to form a plurality of single photodiodes, and each single photodiode of the plurality of single photodiodes comprises the base and the plurality of pins on the base.

7. A photodiode integrating Hall induction manufactured by the manufacturing method for the photodiodes integrating Hall induction according to claim 1.

8. A photoelectric keyboard, comprising a light-emitting diode (LED) key module, wherien the photodiode integrating Hall induction according to claim 7 is provided in the LED key module.

9. The photodiode integrating Hall induction according to claim 7, wherein in the manufacturing method for the photodiodes integrating Hall induction, the step of fixing the visible light emitting chip and the color control chip in the first packaging cavity and fixing the Hall induction chip in the second packaging cavity comprises:
dispensing a chip fixing adhesive in a first designated area in the first packaging cavity and a second designated area in the second packaging cavity respectively;
placing the color control chip, the red light emitting chip, the blue light emitting chip and the green light emitting chip in the first designated area, maintaining a predetermined distance, and bonding the red light emitting chip, the blue light emitting chip and the green light emitting chip with the chip fixing adhesive;
placing the Hall induction chip in the second designated area, and bonding the Hall induction chip with the chip fixing adhesive; and
delivering the support into a curing device and baking the support at a temperature of 150° C.-180°C. and for 60 minutes-80 minutes for curing.

10. The photodiode integrating Hall induction according to claim 7, wherein in the manufacturing method for the photodiodes integrating Hall induction, the plurality of pins comprise a negative power pin, a Hall input pin, a color input pin, a Hall output pin, a color output pin, and a positive power pin;
the step of welding the electrodes of the visible light emitting chip, the color control chip and the Hall induction chip to the plurality of pins respectively to form the electrical control loop comprises:
according to an electrical wiring diagram of the photodiode, welding the color input pin, the color output pin, the positive power pin and the negative power pin with the color control chip and the visible light emitting chip to form the color electrical control loop, and welding the Hall input pin, the Hall output pin, the positive power pin and the negative power pin with the Hall induction chip to form the Hall induction electrical control loop.

11. The photodiode integrating Hall induction according to claim 7, wherein in the manufacturing method for the photodiodes integrating Hall induction, the first packaging cavity is dispensed and packaged with the epoxy resin adhesive or the silica gel, and backed and cured; and the second packaging cavity is dispensed and packaged with the filtering adhesive, and baked and cured, to form the photodiode integrating Hall induction, comprising:
the first packaging cavity is dispensed and packaged with the epoxy resin adhesive or the silica gel, and the second packaging cavity is dispensed and packaged with the filtering adhesive; and
the support dispensed and packaged is transferred into a baking equipment to bake and cure the support at a predetermined temperature, to form the photodiode integrating Hall induction.

12. The photodiode integrating Hall induction according to claim 11, wherein in the manufacturing method for the photodiodes integrating Hall induction, the support dispensed with the packaging adhesive is transferred into the baking equipment to bake and cure the support at the predetermined temperature, comprising:
the support dispensed and packaged is baked in a first stage; in the first stage, a baking temperature is 60° C.-100° C., and a baking time is 60 minutes-80 minutes; and
the support dispensed and packaged is baked in a second stage; in the second stage, a baking temperature is 140° C.-160° C., and a baking time is 60 minutes-80 minutes.

13. The photodiode integrating Hall induction according to claim 7, wherein in the manufacturing method for the photodiodes integrating Hall induction, the support is an integrated support comprising a plurality of bases; the first packaging cavity is dispensed and packaged with the epoxy resin adhesive or the silica gel, and baked and cured; and the second packaging cavity is dispensed and packaged with the filtering adhesive, and baked and cured to form the photodiode integrating Hall induction, also comprising:
the integrated support is cut to form a plurality of single photodiodes, and each single photodiode of the plurality of single photodiodes comprises the base and the plurality of pins on the base.

14. The photoelectric keyboard according to claim 8, wherein in the manufacturing method for the photodiodes integrating Hall induction, the step of fixing the visible light emitting chip and the color control chip in the first packaging cavity and fixing the Hall induction chip in the second packaging cavity comprises:
dispensing a chip fixing adhesive in a first designated area in the first packaging cavity and a second designated area in the second packaging cavity respectively;
placing the color control chip, the red light emitting chip, the blue light emitting chip and the green light emitting chip in the first designated area, maintaining a predetermined distance, and bonding the red light emitting chip, the blue light emitting chip and the green light emitting chip with the chip fixing adhesive;
placing the Hall induction chip in the second designated area, and bonding the Hall induction chip with the chip fixing adhesive; and
delivering the support into a curing device and baking the support at a temperature of 150° C.-180° C. and for 60 minutes-80 minutes for curing.

15. The photoelectric keyboard according to claim 8, wherein in the manufacturing method for the photodiodes integrating Hall induction, the plurality of pins comprise a negative power pin, a Hall input pin, a color input pin, a Hall output pin, a color output pin, and a positive power pin;
the step of welding the electrodes of the visible light emitting chip, the color control chip and the Hall induction chip to the plurality of pins respectively to form the electrical control loop comprises:
according to an electrical wiring diagram of the photodiode, welding the color input pin, the color output pin, the positive power pin and the negative power pin with the color control chip and the visible light emitting chip to form the color electrical control loop, and welding the Hall input pin, the Hall output pin, the positive power pin and the negative power pin with the Hall induction chip to form the Hall induction electrical control loop.

16. The photoelectric keyboard according to claim 8, wherein in the manufacturing method for the photodiodes integrating Hall induction, the first packaging cavity is dispensed and packaged with the epoxy resin adhesive or the silica gel, and backed and cured; and the second packaging cavity is dispensed and packaged with the filtering adhesive, and baked and cured, to form the photodiode integrating Hall induction, comprising:
the first packaging cavity is dispensed and packaged with the epoxy resin adhesive or the silica gel, and the second packaging cavity is dispensed and packaged with the filtering adhesive; and
the support dispensed and packaged is transferred into a baking equipment to bake and cure the support at a predetermined temperature, to form the photodiode integrating Hall induction.

17. The photoelectric keyboard according to claim 16, wherein in the manufacturing method for the photodiodes integrating Hall induction, the support dispensed with the packaging adhesive is transferred into the baking equipment to bake and cure the support at the predetermined temperature, comprising:
the support dispensed and packaged is baked in a first stage; in the first stage, a baking temperature is 60° C.-100° C., and a baking time is 60 minutes-80 minutes; and
the support dispensed and packaged is baked in a second stage; in the second stage, a baking temperature is 140° C.-160° C., and a baking time is 60 minutes-80 minutes.

18. The photoelectric keyboard according to claim 8, wherein in the manufacturing method for the photodiodes integrating Hall induction, the support is an integrated support comprising a plurality of bases; the first packaging cavity is dispensed and packaged with the epoxy resin adhesive or the silica gel, and baked and cured; and the second packaging cavity is dispensed and packaged with the filtering adhesive, and baked and cured to form the photodiode integrating Hall induction, also comprising:
the integrated support is cut to form a plurality of single photodiodes, and each single photodiode of the plurality of single photodiodes comprises the base and the plurality of pins on the base.
